(19) United States
(12) Patent Application Publication
(10) Pub. No.: US 2009/0282662 A1
(43) Pub. Date: Nov. 19, 2009

(54) CAVITATION REACTOR AND METHOD OF PRODUCING HEAT

(76) Inventor: Roger Stringham, Kilauea, HI (US)

Correspondence Address: Vierra Magen Marcus & DeNiro LLP, 575 Market Street, Suite 2500, San Francisco, CA, 94105, US

(21) Appl. No.: 12/480,999

(22) Filed: Jun. 9, 2009

Related U.S. Application Data
(63) Continuation of application No. 10/925,347, filed on Aug. 23, 2004.
(60) Provisional application No. 60/497,059, filed on Aug. 22, 2003.

(51) Int. Cl. H01L 41/22; B23P 11/00

(52) U.S. Cl. 29/25.35; 29/428

(57) ABSTRACT

A cavitation reactor of low mass is disclosed capable of generating more heat than is input. The cavitation reactor may be formed of a variety of fabrication techniques, include techniques used to form semiconductor devices.

### CROSS REFERENCE TO RELATED APPLICATIONS

The present application is a continuation application of patent application Ser. No. 10/925,347, filed Aug. 23, 2004 and entitled, “Cavitation Reactor and Method of Producing Heat,” currently pending, which application is incorporated by reference herein in its entirety, and which application claims priority to provisional patent application Ser. No. 60/497,059, filed Aug. 22, 2003 and entitled “Method of Producing Heat,” which provisional patent application is incorporated by reference herein in its entirety.

### BACKGROUND OF THE INVENTION

1. Field of the Invention

The present invention relates to a system and method of producing heat, and in particular to a system of low mass reactors capable of generating more energy than is input.

2. Description of the Related Art

When certain liquids, such as for example heavy water—D20, are subjected to reduction in pressure of an appropriate duration and magnitude, small pre-existing bubbles of gas and vapor in the liquids expand to some maximum size and then collapse with great violence. This phenomenon is called cavitation, and under proper conditions, the high energy of the collapsing bubble can be directed toward a metal substrate to generate large amounts of heat energy, far in excess of the energy input to the system. One such cavitation reactor for generating energy through cavitation was disclosed in U.S. Pat. No. 4,333,796 to Hugh Flinn, issued in June of 1982. U.S. Pat. No. 4,333,796 is incorporated by reference herein in its entirety.

Existing cavitation reactors to date have not satisfied needs of improved reliability, ease of operation and manufacture and higher efficiencies of energy production as compared to energy input.

### SUMMARY OF THE INVENTION

Embodiments of the invention relate to a cavitation reactor including a piezo capable of being oscillated by a power source, and a working fluid, where the piezo generates cavitation bubbles within said working fluid. The power source may oscillate the piezo at 1.6 MHz. A target is further provided, where the cavitation bubbles are directed into the target to generate energy, where the energy generated is in excess of the energy required to drive the power source.

The cavitation reactor may be fabricated using variety of fabrication methods, including etching and deposition techniques used in fabricating semiconductor devices.

### BRIEF DESCRIPTION OF THE DRAWINGS

The present invention will now be described with reference to the figures, in which:

FIG. 1 shows a cavitation reactor according to an embodiment of the invention used during measurements of sonoluminescence and excess heat production).

FIG. 2 shows a calorimetry set-up according to embodiments of the invention for the cavitation reactor shown in FIG. 1;

FIG. 3 is a graph of heat productions over time according to an embodiment of the cavitation reactor according to the present invention;

FIG. 4 is a graph of the relationship between sonoluminescence and acoustic watts input to the system for three separate tests, A, B and C;

FIG. 5 is a graph of a portion of the data showing the heating and cooling curves generated by the high flow rates through the cavitation reactor of FIG. 1;

FIG. 6 shows illustrative data from a test run where the RF influence and other parameters are shown;

FIG. 7 shows the ganging together of four cavitation reactors according to an embodiment of the present invention;

FIG. 7A shows a piezo including an elastic containment ring thereabout;

FIG. 8 is an embodiment of a system in which the cavitation reactor set-up of FIG. 7 could be used; and

FIG. 9 is an embodiment of a cavitation reactor according to the present invention fabricated using conventional nano-etching technologies.

### DETAILED DESCRIPTION

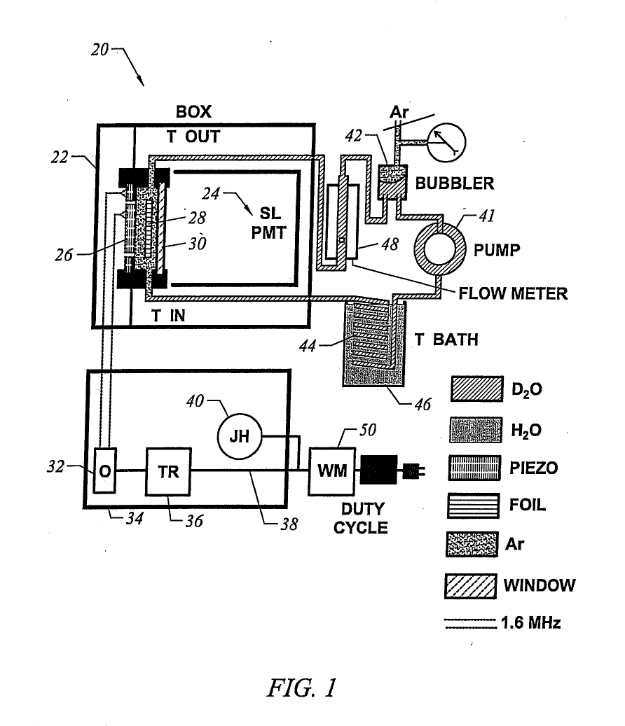

The present invention will now be described reference to FIGS. 1 through 9, which in embodiments of the invention relate to a cavitation reactor and methods of producing heat thereby. It is understood that the present invention may be embodied in many different forms and should not be construed as being limited to the embodiments set forth herein. Rather these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

FIG. 1 shows the cavitation reactor 20 as it used during measurements of SL (sonoluminescence) and Qx (excess heat production). Many of the components shown in FIG. 1 are for the purpose of measuring the properties of the system, such as the input and output temperature of the working fluid and fluid flow rate through the reactor. As set forth hereinafter, many of these components could be omitted in a working reactor. The set-up for measuring the properties of the reactor 20 includes a light box 22 to prevent any light from entering into the system, which light could interfere with the SL measurements. The light box 22 could be formed of various materials including particle board painted black. The light box may be omitted in a working reactor. In the light box are the reactor 20, a PMT (photomutiplier) 24 to convert light into an electric signal which can be measured, and D2O input and output, a piezo 26 for oscillating the D2O, a target 28 and a window 30 to allow measurement by the PMT.

The piezo 26 may be oscillated by a 1.6 MHz input from an oscillator 32 located in calorimetry box 34 along with a transformer 36 associated with the oscillator 32. These components use input watts from the input line 38. To calibrate the calorimetry box a variable Joule heater 40 responds as the only heat source during calibration runs. Outside the box 22 is a pump 41, a bubbler 42 for removing any gas buildup in the reactor and introducing Argon to facilitate SL, a cooling coil 44 and water bath 46 for cooling the D2O before circulating it back into the reactor where T in and T out are measured. Further provided is a calibrated flow meter 48 to regulate the D2O flow through the reactor. Argon pressure is regulated at the bubbler keeping the D2O saturated with argon as it is circulated through the system. The line power input is pulsed to get better measurements because of the RF interference (radio frequency can interfere with data gathering). The duty cycle may be one min. on and one min. off. It is understood that the pump 41, bubbler 42, cooling coil 44, water bath 46 and flow meter 48 may be omitted in a working reactor and that there is no need to cycle the power on and off in a working reactor (the RF interferes with measurement of reactor properties, not operation of the reactor).

The reactor 20 itself is comprised of the piezo 26, the working fluid (argon saturated D2O) and the target 28. It may be cylindrical and approximately 2 cm in diameter and approximately 0.5 cm in depth with a total mass of 17 gm. As explained hereinafter, the reactor 20 may be smaller than that in alternative embodiments. The reactor 20 may be hung by wires in front of the PMT minimizing the conduction of heat to and from the reactor. The window is protected from major cavitation damage by the 100 p target foil, as it is located in front of the window. This reduces the SL measured by the PMT, but there are plenty of photons for good SL measurements. The target may be formed of a variety of materials such as Pd, but other materials include Cu, Ag, Ti.

The cooling bath consists of 2 liters of D2O that has a ⅛ in. diameter and 50 inches long stainless steel coil that is a heat exchanger for the reactor. The pump is an FMI variable liquid volume for the circulation of 20 cc of D2O. The bubbler serves several purposes; the removal gas bubbles from the reactor, the introduction of argon to the system which increases the SL emission, and the visual observation of the D2O circulation and level. The flow meter is calibrated by pumping H2O from the bath through the reactor, flow meter and bubbler and into a volumetric flask while measuring the time shows the flow rate of the flow is correct.

Further details of the above-identified components and reactor, as well as their operation according to the principals of cavitation, are disclosed in applicant's International Application, Publication No. WO 95/16995, entitled “Method For Producing Heat,” which publication is incorporated by reference herein in its entirety.

In embodiments of the present invention, the piezo may be oscillated at 1.6 MHz. This is many times higher than in conventional cavitation reactors. The increased frequency provides for the formation of many more bubbles per unit time as compared to prior devices, with each bubble having the same or greater energy density, but less overall energy as compared to prior devices. Thus, the amount of damage to the target due to cavitation is much reduced relative to prior devices. This lengthens the lifetime of the target foil in a working reactor.

In the embodiment of FIG. 1, in which the reactor is shown in a testing configuration, a high flow D2O rate through the reactor may be provided to remove heat fast so the reactor, piezo and window do not suffer heat damage. Such a flow rate may be 60 cc/min.

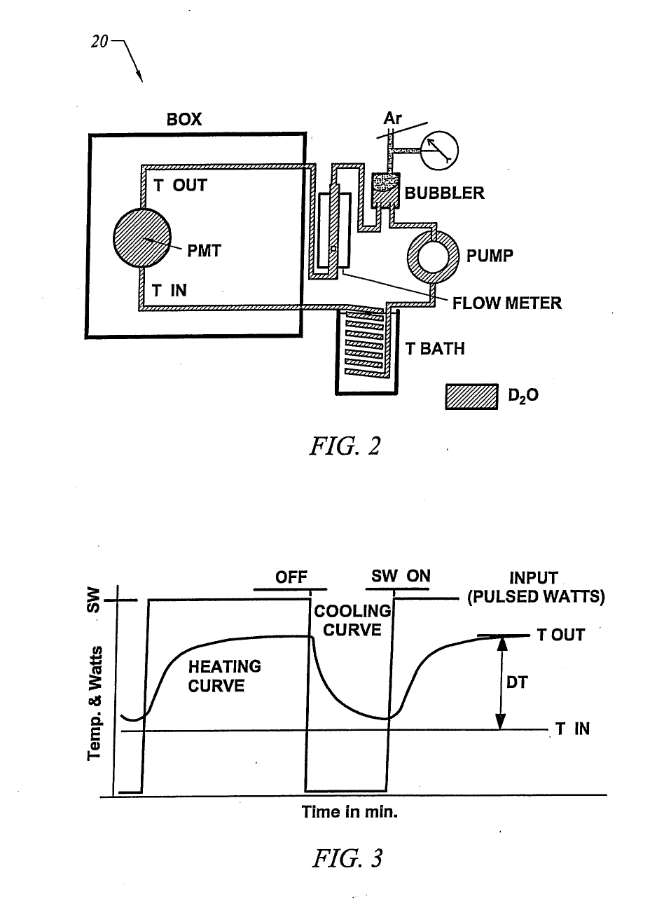

FIG. 2 shows the calorimetry set-up for measuring heat production of the 1.6 MHz cavitation reactor and the data treatment for getting the values for Qx (the excess heat generated in watts). The RF (radio frequency) generated by the 1.6 MHz system interferes with gathering data. This problem may be removed by briefly turning off the power (data is sampled every 5 seconds) and looking at the system for one minute as it cools producing a cooling curve. The reverse is true when the power is turned on a heating curve is produced. A one minute duty cycle may be used showing that the reactor 20 responds quickly to the one minute on and one minute off with the data showing a cooling curve in the off mode and a heating curve in the on mode (FIG. 3). The D2O circulating at about one cc a sec. through the one cc volume reactor with the T in and T out measurement provides the data for the total heat output, Q total, for the low mass reactor. The input heat to the reactor, Q in, is measured as a portion of the total input, Qt, watts passing through the wattmeter 50 (FIG. 1). The calorimetry box in FIG. 1 is calibrated with a variable JH that generates a steady state DT (delta temperature) with each selected JH watt input. This generates a linear plot of DT vs JH watt input and is used to calibrate and measure the heat lost to the TR and O. In embodiments, this results in a value for the acoustic input efficiency for the power supply of 0.30. Qt times 0.30 is the Q in for the reactor. Qx is found by subtracting Q in from Q out.

The low mass of the reactor compared to the mass of working fluid that passes through it (17 gm and 60 gm) makes the system basically a water mass system depending on the flow rate to produce a DT. The data shows some residual heat stored in the mass of the reactor and has a different cooling curve.

FIG. 3 shows the relationship between SL and Q acoustic in (or acoustic watts in) with the data of all runs of series A, B, and C represented. One can see that there is some constancy in the scatter and as the Qx increases so does the SL from the 30 runs sampled. Qx comes from the calorimetry measurements and the SL is from counting photons/sec. (K photons=1000) in the box via a Hamamatsu PMT. What is being counted is the relative number of photons emitted from the reactor window. Two other important results are the reproducibility and the use of the SL collapsing bubble which gives a window to the high density plasma that is transformed into an implanting jet of deuterons. This jet implants deuterons into the lattice of the target foil where some of these high-density deuterons will fuse producing He4 and a heat pulse. The heat pulse is registered in the foil as a vent site seen in SEM FE photos and are in the order of 100 nm in diameter.

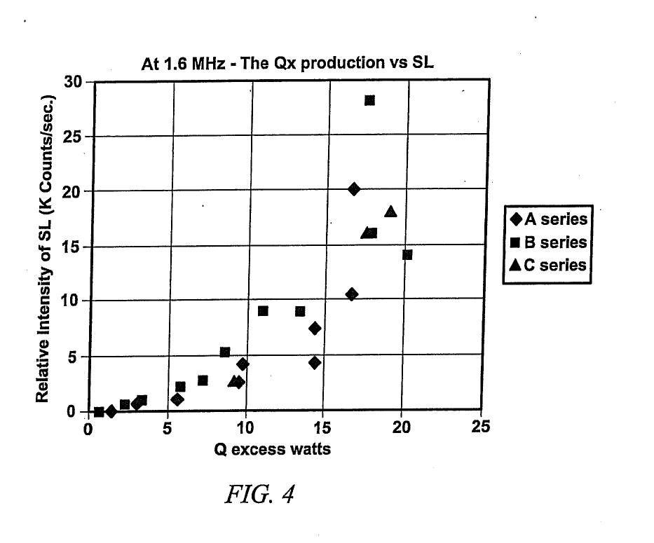

FIG. 4 shows a portion of the measured data in its pseudo steady state pulse mode (i.e., 1 minute on-one minute off) where the heating and cooling curves generated by the high flow rates through the reactor 20 can be seen. Collecting the data at 5 second intervals also shows the LC (induction and capacitance) time factors for the on/off mode. These time delays for completely on or off are in the order of 5 seconds.

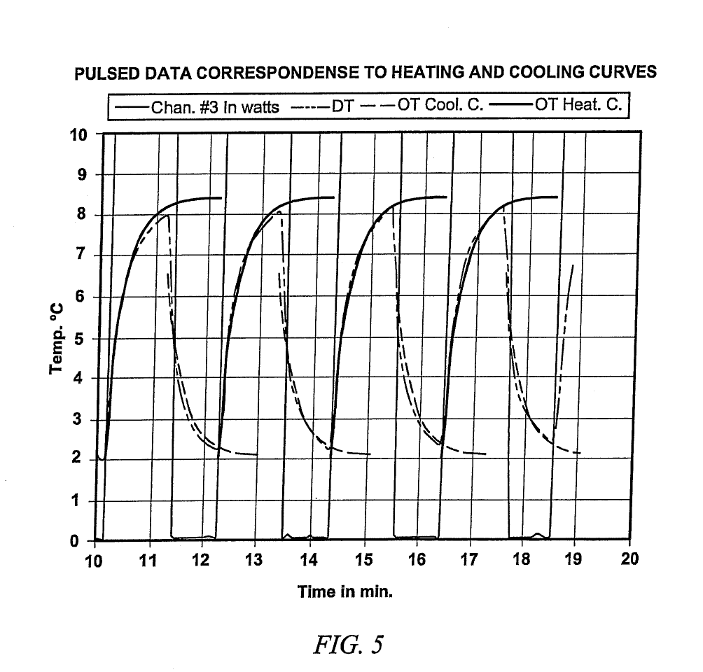

Referring to FIG. 5, the black continuous line is the data and the superimposed red line, the calculated heating curve, and the superimposed blue line, the calculated cooling curve. (Heating curve=SS−DTê(−3t) and the cooling curve=SS+DT(1−ê(−3t)), where SS is a pseudo steadystate.)

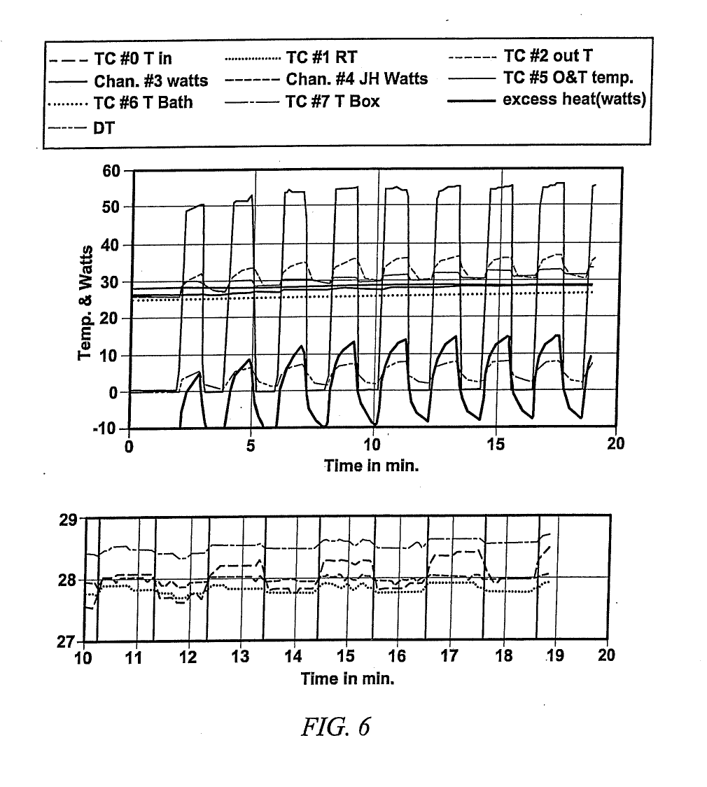

FIG. 6 shows typical data obtained from the reactor 20. The parameters for the test were:

| | |
|---|---|
| Working fluid: | D2O saturated with 14.7 PSIA Argon |
| Target: | Pd#2 |
| Oscillator: | 140 V, 1.6 MHz. |

The RF influence on the T in (blue) and other parameters is shown. By expanding the y scale 0.2 to 0.3 of a degree increase can be seen when the power is in the on mode. The data is generated from K type TC (thermocouples) and WM (wattmeter) inputs to the data gathering system which is measured at five-second intervals.

In the reactor run for the test result shown, there are 10 channels of data: TC for T in, TC for RT, TC for T out, Watts for soni input, Watts for JH input, TC for O & TR, TC for Bath, TC for Box, Watts for Qx, and lastly DT. Also the data for Ar pressure and D2O flow rate of 60 ml/min.

The configuration shown in FIG. 1 is that of the reactor and testing equipment to measure the various properties of the system including T in of the D2O, T out of the D2O and flow rate. However, a working embodiment of the reactor 20 may be a sealed device having only the piezo 26, the working fluid such as the D2O and argon, and the target encased within a housing. The piezo 26 in such an embodiment may be connected via leads to the oscillator and transformer. When power is applied to oscillate the piezo, the reactor begins generating heat which may be used as a power source. Such a reactor may have a small size, such as for example about 2 cm. in diameter and about 0.5 cm. deep, and total mass of 17 gm. The reactor may be smaller or larger than that in alternative embodiments.

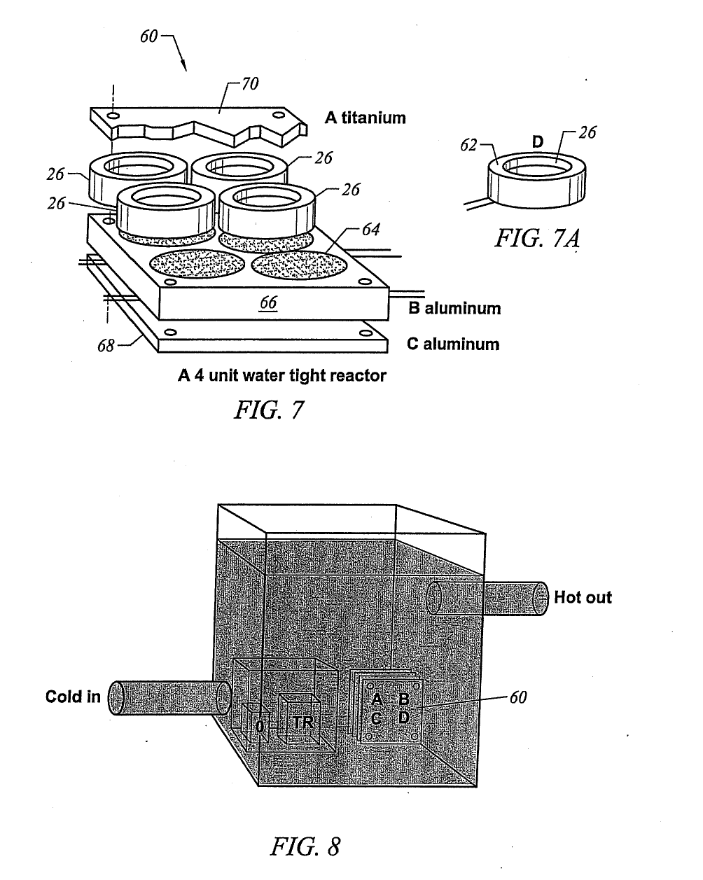

It is contemplated that a single reactor 20 comprised of a piezo and target may be provided within a housing according to the present invention. Alternatively, a plurality of such reactors may be provided within a housing. Such an embodiment is shown in FIG. 7. FIG. 7 shows the ganging together of four reactors without all accessories used for measurements. The reactor assembly 60 may include individual piezos 26, each surrounded by an elastic containment ring 62. The rings 62 and piezos 26 fit into corresponding wells 64 in a body 66. The body 66 may have a bottom plate 68, and a top plate 70. In embodiments of the invention, the target may be provided within the interior of each of the piezos 26. In alternative embodiments, the top plate 70 itself may be the target for each of the piezos.

The bottom plate 68 may be for example aluminum and it seals the 1.6 MHz electric supply with a gasket, which may be for example teflon. The main body 66 may also be aluminum and provides a housing and support for the four piezos and in aluminum circular wells. The 4 piezos in their rubberized containment in the wells are filled with Ar saturated D2O. In one embodiment, this can be done by freezing the D2O, placing them in the wells along with the piezos and containment rings, then quickly sealing with another teflon gasket with the top plate 70 and bolting the assembly together. The top plate 70 may be titanium and is sealed with a gasket with 4 holes allowing the Ti to be the target for cavitation bubble jets. Once secure, the assembly is prevented from leaking. It is understood that the choice of materials set forth above may vary in alternative embodiments. Moreover, it is understood that the number of piezos 26 provided within the assembly 60 may be lesser than or greater than four in alternative embodiments. The power source may also oscillate the piezos at less than or greater than 1.6 MHz in alternative embodiments.

Referring to FIG. 8, the operation of the ganged system 60 may use a 50 volt transformer and an oscillator system to drive the piezos just as in the single unit. Placing the system in water along with the TR and O allows for the capture of all the input heat including Qx. The water can circulate for space heating purposes. The system works as a power multiplier with, for example, 200 watts in and 400 watts out. Larger collections of units will produce more Qx. It is understood that the heat generated by the assembly 60 may be used in a variety of other applications.

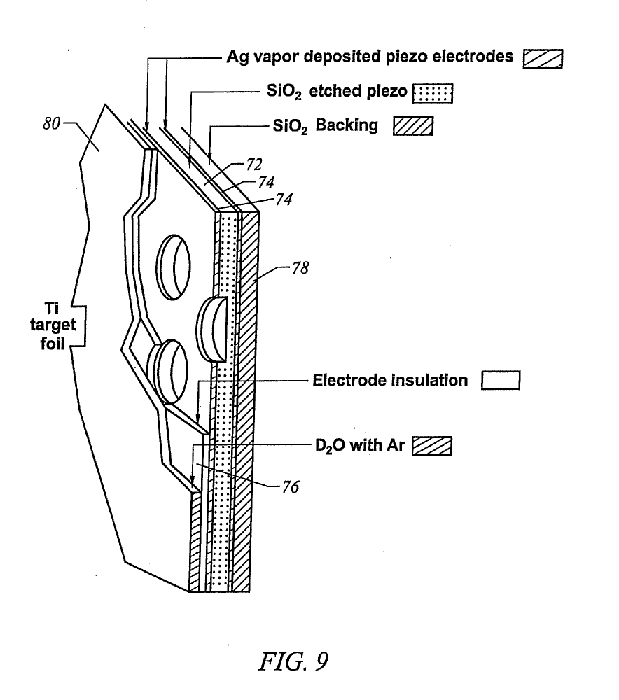

The assembly of FIG. 7 may be fabricated according to a variety of fabrication techniques, such as conventionally machining and assembling the components. In a further embodiment, the assembly shown in FIG. 7 may be formed using the same techniques for forming semiconductors. Such embodiments are shown in FIG. 9. As shown therein, the piezo 72 may be a 1 mm thick SiO2 sheet that has a vapor deposition layer 74 of Ag on both surfaces which serve as the electrodes for the input signal that drive the piezo sheet. On the backside of one of the electrodes is another SiO2 sheet 78 that insulates one of the Ag electrodes. The other piezo electrode is coated with an insulator 76 that is etched through and ⅔ into the 1 mm quartz piezo. The piezo and ceramic insulator has etched holes that are 1 mm in diameter and 1 mm deep and are filled with frozen D2O saturated with Ar gas or liquid. The ceramic is quickly bonded to the Ti foil layer 80 that forms a closure to each individual reactor in the quartz (SiO2) piezo. This system is powered by simple electronics of a feedback nature as is known in the art. It is understood that instead of having layer 80 as the target layer, the target may be provided within the interior of wells formed in the piezo layer.

The quick heat removal from the system is an important feature as each micro cavitation reactor is capable of producing 3 watts of Qx. A ten by ten cm. array might produce 1200 watts of Qx.

Although the invention has been described in detail herein, it should be understood that the invention is not limited to the embodiments herein disclosed. Various changes, substitutions and modifications may be made thereto by those skilled in the art without departing from the spirit or scope of the invention as described and defined by the appended claims.

What is claimed is:

1. A method of forming a cavitation reactor, the method comprising the steps of:
forming a piezo capable of being oscillated by a power source;
depositing a first layer on a first side of the piezo, the first layer forming a first electrode to drive the piezo;
depositing a second layer on a second side of the piezo, the second layer forming a second electrode to drive the piezo;
depositing a first insulator on the first layer;
depositing a second insulator on the second layer;
etching an opening through the first insulator, first electrode and partially through the piezo;
at least partially filling the opening with a working fluid, the piezo generating cavitation bubbles within said working fluid;
bonding a target to the first insulator to seal the opening; and
directing said cavitation bubbles into said target.

2. The method of claim 1, said step of forming a piezo comprising the step of forming a piezo of silicon dioxide.

3. The method of claim 2, said step of forming a piezo comprising the step of forming a piezo having a thickness of about 1 mm.

4. The method of claim 1, said step of depositing the first and second layers comprising the steps of depositing the first and second layers by vapor deposition.

5. The method of claim 1, said step of depositing the first and second layers comprising the steps of depositing silver on the piezo.

6. The method of claim 1, said step of at least partially filling the opening with a working fluid comprising the step of at least partially filling the opening with deuterium oxide.

7. The method of claim 6, said step of at least partially filling the opening with deuterium oxide comprising the step of at least partially filling the opening with frozen deuterium oxide.

8. The method of claim 1, further comprising the step of providing a current to the electrodes to drive the piezo.

9. The method of claim 1, said step of bonding the target to the first insulator comprising the step of bonding titanium to the first insulator.

10. A method of forming a cavitation reactor, the method comprising the steps of:
forming a piezo capable of being oscillated by a power source;
depositing a first layer on a first side of the piezo, the first layer forming a first electrode to drive the piezo;
depositing a second layer on a second side of the piezo, the second layer forming a second electrode to drive the piezo;
depositing a first insulator on the first layer;
depositing a second insulator on the second layer;
etching an opening through the first insulator, first electrode and partially through the piezo;
at least partially filling the opening with a working fluid, the piezo generating cavitation bubbles within said working fluid;
providing a target within the opening, said cavitation bubbles being directed into said target to generate energy;
sealing the opening.

11. The method of claim 10, said step of forming a piezo comprising the step of forming a piezo of silicon dioxide.

12. The method of claim 11, said step of forming a piezo comprising the step of forming a piezo having a thickness of about 1 mm.

13. The method of claim 10, said step of depositing the first and second layers comprising the steps of depositing the first and second layers by vapor deposition.

14. The method of claim 10, said step of depositing the first and second layers comprising the steps of depositing silver on the piezo.

15. The method of claim 10, said step of at least partially filling the opening with a working fluid comprising the step of at least partially filling the opening with deuterium oxide.

16. The method of claim 15, said step of at least partially filling the opening with deuterium oxide comprising the step of at least partially filling the opening with frozen deuterium oxide.

17. The method of claim 10, further comprising the step of providing a current to the electrodes to drive the piezo.

18. The method of claim 10, said step of providing the target within the opening comprising the step of providing titanium within the opening.

19. A method of forming a cavitation reactor, the method comprising the steps of:
depositing by vapor deposition a first electrode layer onto a first insulating layer;
depositing a piezo layer onto the first electrode layer;
depositing by vapor deposition a second electrode layer onto the piezo layer on a side of the piezo layer opposite the first electrode layer;
depositing a second insulating layer onto the second electrode layer on a side of the second electrode layer opposite the piezo layer;
etching at least one opening through the second insulating layer, the second electrode layer and partially through the piezo layer;
at least partially filling the opening with a working fluid, the piezo generating cavitation bubbles within said working fluid;
providing a target within the opening, said cavitation bubbles being directed into said target to generate energy;
sealing the opening.

20. The method of claim 19, said step of depositing a piezo layer comprising the step of depositing a piezo layer of silicon dioxide, and said step of at least partially filling the opening with a working fluid comprising the step of at least partially filling the opening with a working fluid of with frozen deuterium oxide.
